(19) United States
(12) Patent Application Publication
(10) Pub. No.: US 2026/0179700 A1
(43) Pub. Date: Jun. 25, 2026

(54) INFORMATION PROCESSING SYSTEM AND NON-TRANSITORY COMPUTER READABLE MEDIUM

(71) Applicant: FUJIFILM Business Innovation Corp., Tokyo (JP)

(72) Inventor: Binhui LIU, Kanagawa (JP)

(73) Assignee: FUJIFILM Business Innovation Corp., Tokyo (JP)

(21) Appl. No.: 19/187,151

(22) Filed: Apr. 23, 2025

(30) Foreign Application Priority Data
Dec. 24, 2024 (JP) 2024-227788

(51) Int. Cl. G11C 16/34

(52) U.S. Cl. CPC G11C 16/349

(57) ABSTRACT

An information processing system includes a processor configured to: record a usage history of each component in a different sector of a non-volatile memory; and record a cumulative write count of each sector in which a usage history of a corresponding component is recorded, in a sector different from any sector in which a usage history of any component is recorded.

### CROSS-REFERENCE TO RELATED APPLICATIONS

This application is based on and claims priority under 35 USC 119 from Japanese Patent Application No. 2024-227788 filed Dec. 24, 2024.

### BACKGROUND

### (i) Technical Field

The present disclosure relates to an information processing system and a non-transitory computer readable medium.

### (ii) Related Art

Japanese Unexamined Patent Application Publication No. 2023-059119 discloses an image forming apparatus that prevents the rewrite count of a consumable article memory from reaching an upper limit value when a consumable article is refilled with a printing material in a state in which the consumable article memory is not replaced.

Japanese Unexamined Patent Application Publication No. 2007-331356 discloses an image forming apparatus capable of extending the life of a data-holding function using an electrically erasable and programmable read-only memory (EEPROM) while guaranteeing the contents of held data.

### SUMMARY

In order to determine whether a component included in a product is reusable, it has been proposed that the usage history of each component is recorded in a non-volatile memory. A usage history is a value indicating the usage count or usage time of each component.

The non-volatile memory has a limit on the write count for each sector. For this reason, the remaining lifetime of a sector can be acquired by recording the usage history of each component in each sector and using the usage history as information on the write count of the sector.

However, when a component is replaced due to a failure or the like, if the usage history is reset in correspondence with the replaced component, a problem arises in that the accurate remaining lifetime of a sector cannot be acquired.

Aspects of non-limiting embodiments of the present disclosure relate to providing an information processing system and a non-transitory computer readable medium capable of acquiring the accurate remaining lifetime of a sector even when a component is replaced in a case where the usage history of the component is recorded in each sector of a non-volatile memory.

Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided an information processing system including a processor configured to: record a usage history of each component in a different sector of a non-volatile memory, and record a cumulative write count of each sector in which a usage history of a corresponding component is recorded, in a sector different from any sector in which a usage history of any component is recorded.

### BRIEF DESCRIPTION OF THE DRAWINGS

An exemplary embodiment of the present disclosure will be described in detail based on the following figures, wherein:

FIG. 1 is an external view of an image forming apparatus of an exemplary embodiment of the present disclosure;

FIG. 2 is a block diagram illustrating a hardware configuration of the image forming apparatus;

FIG. 3 is a diagram for describing information recorded in a shared electrically erasable and programmable read-only memory (SEEPROM) of the image forming apparatus;

FIG. 4 is a diagram for describing processing related to recycle counters at the time of replacement of a component in the image forming apparatus;

FIG. 5 is a diagram for describing the processing related to the recycle counters at the time of replacement of a component in the image forming apparatus; and

FIG. 6 is a flowchart illustrating a flow of the processing related to the recycle counters at the time of replacement of a component in the image forming apparatus.

### DETAILED DESCRIPTION

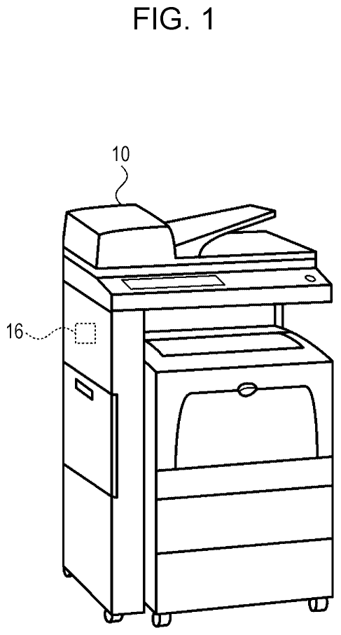

Hereinafter, an exemplary embodiment for carrying out the technology of the present disclosure will be described in detail with reference to the drawings. FIG. 1 is an external view of an image forming apparatus of the exemplary embodiment.

An image forming apparatus 10 illustrated in FIG. 1 is an apparatus called a multifunction peripheral that has multiple functions such as a copy function, a print function, a fax function, and a scan function. The image forming apparatus 10 is an example of an information processing system in the technology of the present disclosure.

The image forming apparatus 10 is equipped with an SEEPROM 16. The image forming apparatus 10 records the usage history of each component in the SEEPROM 16 and thus can determine whether the component included in the image forming apparatus 10 is reusable. A usage history is a value indicating the usage count or usage time of each component.

The SEEPROM 16 is an example of a non-volatile memory in the technology of the present disclosure. The non-volatile memory installed in the image forming apparatus 10 is not limited to an SEEPROM, and may be another type of memory.

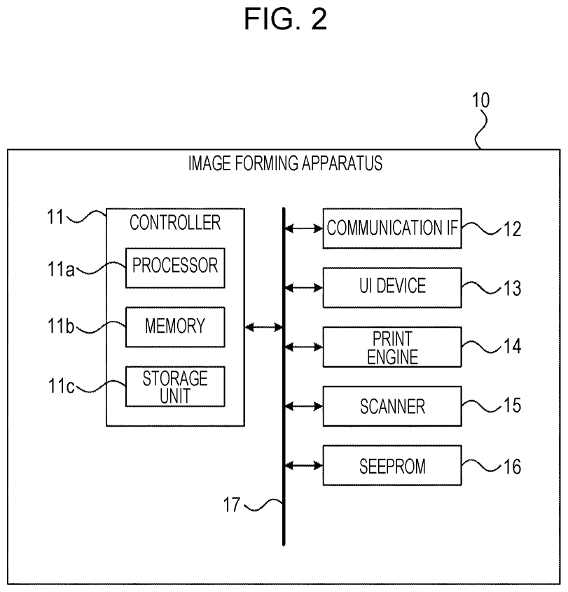

Next, a hardware configuration of the image forming apparatus 10 of the present exemplary embodiment will be described. FIG. 2 is a block diagram illustrating the hardware configuration of the image forming apparatus 10.

As illustrated in FIG. 2, the image forming apparatus 10 includes a controller 11, a communication interface (abbreviated as communication IF) 12, a user interface device (abbreviated as UI device) 13, a print engine 14, a scanner 15, and the SEEPROM 16. These components are connected to each other via a control bus 17.

The controller 11 includes a processor 11a, a memory 11b, and a storage unit 11c. The processor 11a executes predetermined processing on the basis of a program read from the storage unit 11c and loaded into the memory 11b. For example, the storage unit 11c includes a read-only memory (ROM), a hard disk drive (HDD), or a solid-state drive (SSD). Various programs, data, and the like are stored in the storage unit 11c.

While a case in which the processor 11a reads and executes a program stored in the storage unit 11c has been described in the present exemplary embodiment, the present disclosure is not limited to such a case. The program may be provided after being recorded on a computer-readable recording medium as described above. The program may be acquired from an external device via a communication line.

The communication IF 12 performs data transmission and reception with an external device or the like. For example, the UI device 13 is a device for a user to receive or input information, such as a touch panel and/or a button. The print engine 14 prints an image on a recording medium such as printing paper through processes such as charging, exposure, development, transfer, and fixing. The scanner 15 reads a document placed at the image forming apparatus 10 and outputs image data in a set image format. The SEEPROM 16 is a memory for recording the usage history of each component.

As described above, the image forming apparatus 10 records the usage history of each component in the SEEPROM 16 so as to be able to determine whether the component included in the image forming apparatus 10 is reusable. In the following description, a value that records the usage history of each component may be referred to as a recycle counter.

The non-volatile memory such as the SEEPROM 16 has a limit on the write count for each sector. For this reason, the remaining lifetime of a sector can be acquired by recording the usage history of each component in each sector and using the usage history as information on the write count of the sector.

However, when a component is replaced due to a failure or the like, if the usage history is reset in correspondence with the replaced component, a problem arises in that the accurate remaining lifetime of a sector cannot be acquired.

In order to solve such a problem, the controller 11 of the image forming apparatus 10 of the present exemplary embodiment records a usage history of each component in a different sector of the SEEPROM 16, and records a cumulative write count of each sector in which a usage history of a corresponding component is recorded, in a sector different from any sector in which a usage history of any component is recorded.

In the present exemplary embodiment, when the cumulative write count of a sector in which a usage history of a component is recorded satisfies a preset condition at the time of replacement of the component, the controller 11 may record the usage history of the component in a sector different from the sector that has been used.

In this case, the preset condition may be that a numerical value obtained by adding a preset reference value to the cumulative write count of the sector in which the usage history of the component having been subjected to the replacement is recorded exceeds a numerical value set as the upper limit write count of each sector.

In this case, the preset reference value may be a numerical value set as a write count expected for one component.

Information recorded in the SEEPROM 16 in the image forming apparatus 10 of the present exemplary embodiment will be described in detail.

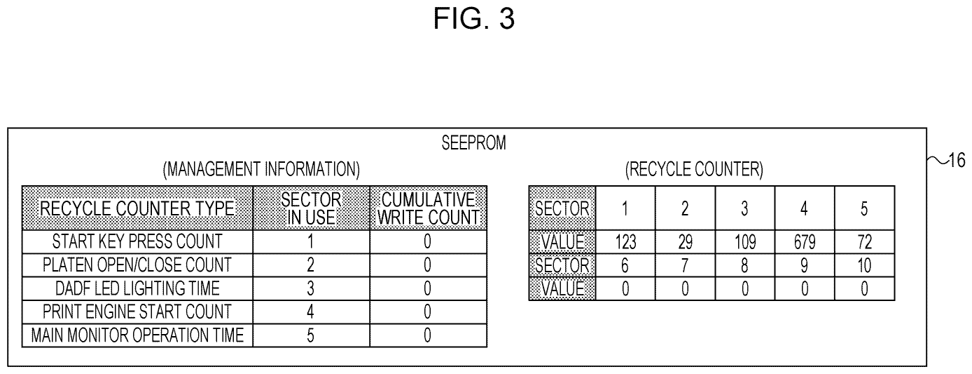

As illustrated in FIG. 3, recycle counters and management information for managing the recycle counters are recorded in the SEEPROM 16.

A recycle counter is a value that records the usage history of each component, and is recorded in a different sector for each component.

Management information is information for managing the recycle counters, and includes information on the type of the usage history corresponding to each component, a sector in which the usage history of the component is recorded, and the cumulative write count of the sector in which the usage history of the component is recorded.

At the time of factory shipment of the image forming apparatus 10, “0” is input as the “cumulative write count of sector”. The numerical value of “cumulative write count of sector” is not updated each time writing is performed in each sector, but is updated at the time of replacement of a component. This point will be described in detail below.

As an example, “1” is set for the “sector in use” for recording a start key press count, which is a usage history related to the life of a start key, at the time of factory shipment of the image forming apparatus 10.

“3” is set for the “sector in use” for recording a duplex automatic document feeder (DADF) LED lighting time, which is a usage history related to the life of a light emitting diode (LED) mounted on a DADF, at the time of factory shipment of the image forming apparatus 10.

In the present exemplary embodiment, when the usage history is the usage count, the recycle counter is incremented each time a component is used once. When the usage history is the usage time, the recycle counter is incremented each time a component is used for one hour.

To reduce the write count of a sector, the recycle counter may be incremented every time a component is used multiple times or every time a component is used for multiple hours.

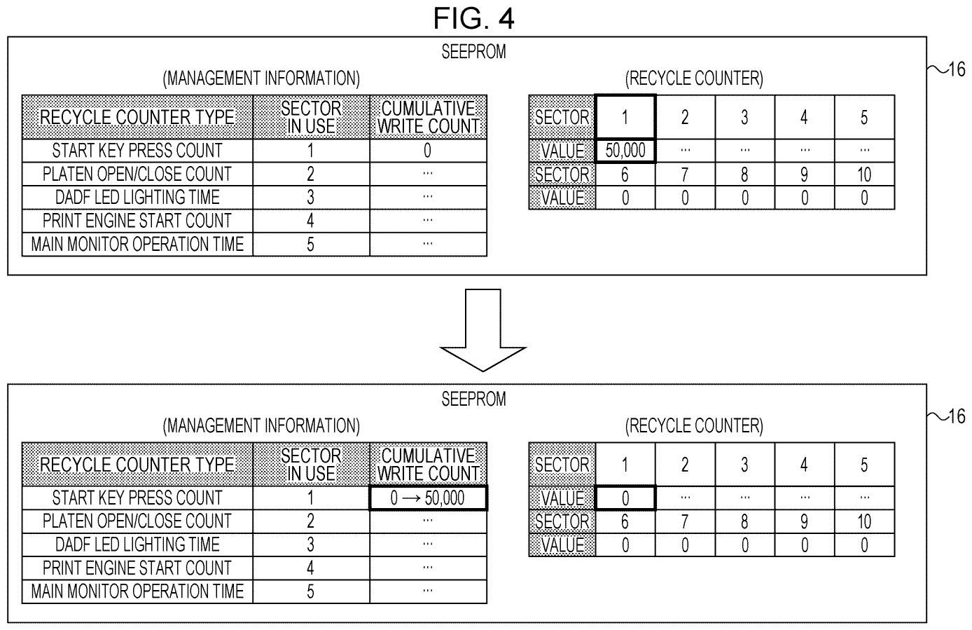

For example, assume that the (first) start key at the time of factory shipment of the image forming apparatus 10 fails when it is used 50,000 times, and the start key is replaced with a new component. In this case, as illustrated in FIG. 4, the controller 11 clears the numerical value of the recycle counter in a sector 1 in which the start key press count is recorded to zero.

The controller 11 records the numerical value “50,000”, which is obtained by adding the value “50,000” at the time of replacement of the component to the currently input numerical value “0”, as the cumulative write count of the sector 1 in which the start key press count is recorded.

Although not illustrated, assume that the second (replacement) start key fails when it is used 100,000 times, and the start key is replaced with a new component, i.e., a third start key. In this case, the controller 11 clears the numerical value of the recycle counter in the sector 1 in which the start key press count is recorded to zero.

The controller 11 records the numerical value “150,000”, which is obtained by adding the value “100,000” at the time of replacement of the component to the currently input numerical value “50,000”, as the cumulative write count of the sector 1 in which the start key press count is recorded.

There is an upper limit to the cumulative write count of each sector. As an example, the upper limit is 1,000,000 times. It is assumed that the maximum write count expected for one component is 200,000 times. The numerical value of the expected write count may vary for each component.

In this case, the controller 11 sets 200,000 as a reference value and 1,000,000 as a threshold. When a numerical value obtained by adding the reference value (200,000 in this case) to the cumulative write count of the sector in which the usage history of the component having been subjected to replacement is recorded exceeds the threshold (1,000,000 in this case) at the time of the replacement of the component, the controller 11 records the usage history of the component in a sector different from the sector that has been used.

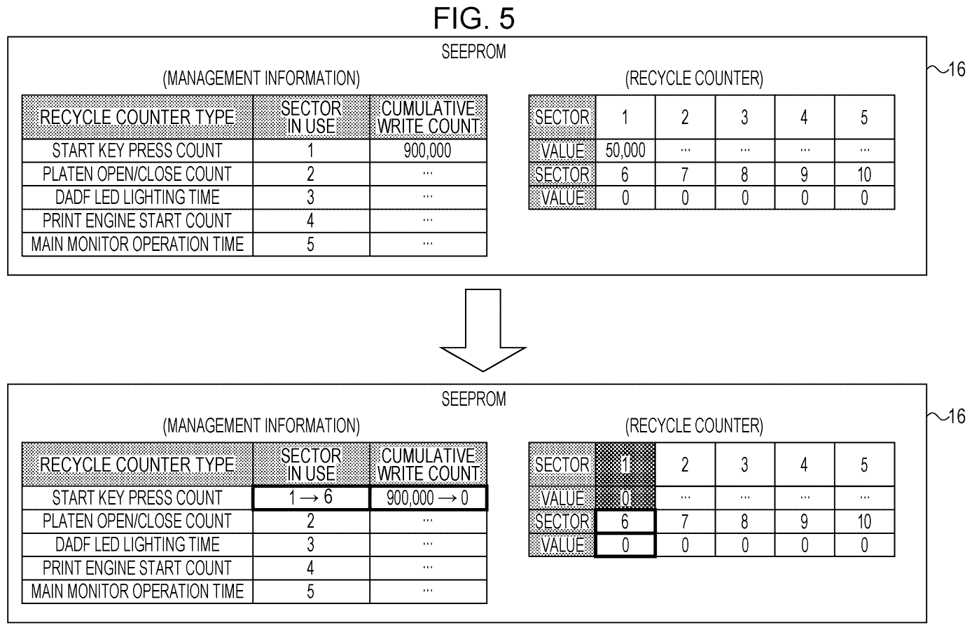

Specifically, as illustrated in FIG. 5, assume that the start key fails in a state where “900,000” is recorded as the cumulative write count of the sector 1 in which the start key press count is recorded, and the start key is replaced with a new component.

In this case, since the numerical value obtained by adding the reference value “200,000” to “900,000” exceeds the threshold “1,000,000”, the controller 11 stops using the sector 1 as the sector in which the start key press count is recorded, and newly uses a sector 6 which is a sector with the smallest number among free sectors.

To start using the sector 6 anew, the controller 11 clears the numerical value of the cumulative write count to zero.

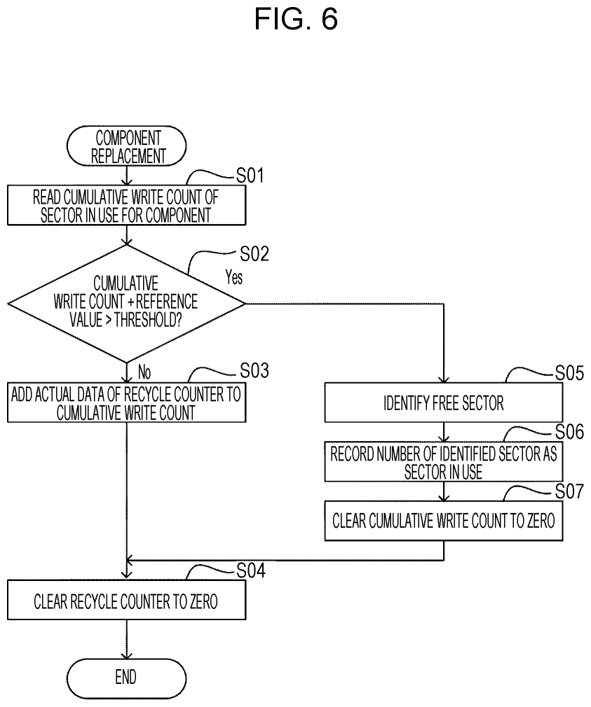

Next, with reference to a flowchart of FIG. 6, description is given of a flow of processing related to recycle counters at the time of replacement of a component in the image forming apparatus 10 of the present exemplary embodiment.

When a component of the image forming apparatus 10 is replaced, in step S01, the controller 11 reads the cumulative write count of the sector in use for the component.

Next, in step S02, the controller 11 determines whether a numerical value obtained by adding the reference value to the cumulative write count of the sector in use for the component exceeds the threshold.

When the numerical value obtained by adding the reference value to the cumulative write count of the sector in use for the component does not exceed the threshold in step S02, the controller 11 adds the actual data of the recycle counter to the cumulative write count in step S03.

Next, in step S04, the controller 11 clears the recycle counter for the component to zero, and ends the processing.

When the numerical value obtained by adding the reference value to the cumulative write count of the sector in use for the component exceeds the threshold in step S02, the controller 11 identifies a free sector in step S05 and records the number of the identified sector in the management information as the sector in use in step S06.

Next, in step S07, the controller 11 clears the cumulative write count of the sector corresponding to the component to zero.

Next, in step S04, the controller 11 clears the recycle counter for the component to zero, and ends the processing.

### Modifications

While the image forming apparatus 10 of an exemplary embodiment of the present disclosure has been described above, the technology of the present disclosure is not limited to the above-described exemplary embodiment and may be modified as appropriate.

In the embodiments above, the term “processor” refers to hardware in a broad sense. Examples of the processor include general processors (e.g., CPU: Central Processing Unit) and dedicated processors (e.g., GPU: Graphics Processing Unit, ASIC: Application Specific Integrated Circuit, FPGA: Field Programmable Gate Array, and programmable logic device).

In the embodiments above, the term “processor” is broad enough to encompass one processor or plural processors in collaboration which are located physically apart from each other but may work cooperatively. The order of operations of the processor is not limited to one described in the embodiments above, and may be changed.

In the technology of the present disclosure, a system includes both a system constituted by a plurality of devices and a system constituted by a single device.

The technology of the present disclosure may also be applied to a program and a program product.

### APPENDIX

(((1)))

An information processing system comprising:
a processor configured to:
   record a usage history of each component in a different sector of a non-volatile memory; and
record a cumulative write count of each sector in which a usage history of a corresponding component is recorded, in a sector different from any sector in which a usage history of any component is recorded.
(((2)))

The information processing system according to (((1))), wherein
the processor is configured to,
when the cumulative write count of a sector in which a usage history of a component is recorded satisfies a preset condition at a time of replacement of the component, record the usage history of the component in a sector different from the sector that has been used.
(((3)))

The information processing system according to (((2))), wherein
the preset condition is that a numerical value obtained by adding a preset reference value to the cumulative write count of the sector in which the usage history of the component having been subjected to the replacement is recorded exceeds a numerical value set as an upper limit write count of the sector.
(((4)))

The information processing system according to (((3))), wherein
the preset reference value is a numerical value set as a write count expected for one component.
(((5)))

The information processing system according to any one of (((1))) to (((4))), wherein
the non-volatile memory is an SEEPROM.
(((6)))

A program causing a computer to execute a process comprising:
recording a usage history of each component in a different sector of a non-volatile memory; and
recording a cumulative write count of each sector in which a usage history of a corresponding component is recorded, in a sector different from any sector in which a usage history of any component is recorded.

What is claimed is:

1. An information processing system comprising:
a processor configured to:
record a usage history of each component in a different sector of a non-volatile memory; and
record a cumulative write count of each sector in which a usage history of a corresponding component is recorded, in a sector different from any sector in which a usage history of any component is recorded.

2. The information processing system according to claim 1, wherein
the processor is configured to,
when the cumulative write count of a sector in which a usage history of a component is recorded satisfies a preset condition at a time of replacement of the component, record the usage history of the component in a sector different from the sector that has been used.

3. The information processing system according to claim 2, wherein
the preset condition is that a numerical value obtained by adding a preset reference value to the cumulative write count of the sector in which the usage history of the component having been subjected to the replacement is recorded exceeds a numerical value set as an upper limit write count of the sector.

4. The information processing system according to claim 3, wherein
the preset reference value is a numerical value set as a write count expected for one component.

5. The information processing system according to claim 1, wherein
the non-volatile memory is an SEEPROM.

6. A non-transitory computer readable medium storing a program causing a computer to execute a process comprising:
recording a usage history of each component in a different sector of a non-volatile memory; and
recording a cumulative write count of each sector in which a usage history of a corresponding component is recorded, in a sector different from any sector in which a usage history of any component is recorded.
